(19) United States
(12) Patent Application Publication
(10) Pub. No.: US 2006/0109157 A1
(43) Pub. Date: May 25, 2006

(54) Apparatus and method for detecting voltage of an A/D converter

(75) Inventor: Hwal-Am Lee, Hwaseong-gun (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/281,715

(22) Filed: Nov. 18, 2005

(30) Foreign Application Priority Data
Nov. 19, 2004 (KR) 2004-0095060

(51) Int. Cl. H03M 1/12

(52) U.S. Cl. 341/155

(57) ABSTRACT

An apparatus and method are provided for detecting the voltage of an analog-to-digital converter. The apparatus comprises an analog-to-digital converter converting an analog signal into a digital signal, and a constant voltage device having one end connected to an input signal Vs to be detected, and a second end connected to an input terminal of the analog-to-digital converter. The constant voltage device is maintained at a constant voltage level Vz. The method comprises lowering the voltage of an predetermined voltage using a constant voltage device, converting the voltage-lowered input signal into a digital signal using the analog-to-digital converter, and compensating for voltage deviation of the constant voltage device with respect to the digital signal.

### PRIORITY

This application claims the benefit under 35 U.S.C. § 119(a) of Korean Patent Application No. 10-2004-0095060, filed on Nov. 19, 2004, in the Korean Intellectual Property Office, the entire disclosure of which is hereby incorporated by reference.

### BACKGROUND OF THE INVENTION

1. Field of the Invention

The present invention relates to analog-to-digital (A/D) converters. More particularly, the present invention relates to an apparatus and method for precisely detecting the voltage of an A/D converter using a zener diode.

2. Description of the Related Art

FIG. 1 depicts a block diagram of a conventional analog-to-digital (A/D) converting system that includes an A/D converter 100 and voltage splitting resistors R1 and R2. When the supply voltage Vdd applied to A/D converter 100 is greater than a voltage Vs to be detected, the voltage Vs is divided into voltage Vi using the voltage splitting resistors R1 and R2, the voltage Vi being smaller than the supply voltage Vdd. Next, A/D conversion is performed on the voltage Vi to convert voltage Vi into a digital signal. The voltage Vi is computed by:
Vi=Vs×R2/(R1+R2)<Vdd (1)

When a signal or voltage Vs to be detected is divided into voltage Vi using the voltage splitting resistors R1 and R2, variation in the voltage Vs is also divided, thus reducing variation in the divided voltage Vi. Accordingly, precision of the A/D conversion is lowered. Variation in voltage Vi is computed by:
variation in Vi=variation in Vs×R2/(R1+R2)<variation in Vs (2)

For example, if voltage Vs to be detected is 20 to 30 V, which is far greater than the 3.3 V or 5 V supply voltage Vdd of a general A/D converter, variation in voltage Vs can be 1 V. In this example, variation in the voltage Vi is reduced to 0.1 V and, therefore, the A/D converter 100 detects less than 10% of the variation in the voltage Vs. Accordingly, the precision of a conventional A/D converter 100 is remarkably low.

### SUMMARY OF THE INVENTION

Aspects of the present invention provide an apparatus and method for detecting the voltage of an analog-to-digital (A/D) converter by amplifying variation in voltage applied to the A/D converter when the voltage to be detected is far greater than the supply voltage Vdd applied to the A/D converter.

According to one exemplary embodiment of the present invention, there is provided an apparatus for detecting voltage of an analog-to-digital converter, the apparatus comprising an analog-to-digital converter for converting an analog signal into a digital signal, and a constant voltage device having a first end connected to an input signal Vs to be detected and a second end connected to an input terminal of the analog-to-digital converter, the constant voltage device being maintained at a constant voltage level Vz. The apparatus may further comprise a resistor having one end connected to ground and the other end connected to both the second end of the constant voltage device and the input terminal of the analog-to-digital converter. The apparatus may still further comprise a deviation calculator for computing and storing a voltage deviation Vcal between voltages Vi_math and Vi_cal, and a deviation compensator for compensating for voltage deviation of the constant voltage device by reflecting the voltage deviation Vcal into an output of the analog-to-digital converter, wherein Vi_math denotes an input voltage of the analog-to-digital converter when the constant voltage Vz has an ideal value with respect to the input signal Vs, and Vi_cal denotes a calibrated input voltage of the analog-to-digital converter, which represents the actual or measured voltage drop across the constant voltage device.

According to another aspect of the present invention, there is provided a method of detecting the voltage of an analog-to-digital converter, the method comprising lowering an input signal by a predetermined voltage using a constant voltage device. The method further comprises converting the voltage-lowered input signal into a digital signal using the analog-to-digital converter, and compensating for voltage deviation of the constant voltage device with respect to the digital signal.

The constant voltage device may be a zener diode. Deviation of the voltage Vz of the zener diode may be obtained by computing a difference between voltages Vi_math and Vi_cal, wherein Vi_math denotes an input voltage of the analog-to-digital converter when the constant voltage Vz of the zener diode has an ideal value with respect to input signal Vs, and Vi_cal denotes a calibrated input voltage of the analog-to-digital converter, which represents the actual or measured voltage drop across the zener diode.

According to another aspect of the present invention, there is provided a computer readable medium having stored thereon instructions for detecting a voltage of an analog-to-digital converter.

### BRIEF DESCRIPTION OF THE DRAWINGS

The above and other aspects and advantages of the present invention will become more apparent by describing in detail exemplary embodiments thereof with reference to the attached drawings, in which like reference numerals will be understood to refer to like parts, components and structure, where:

FIG. 1 depicts a block diagram of a conventional analog-to-digital (A/D) converter;

FIG. 2 depicts a block diagram of an apparatus for detecting the voltage of an A/D converter according to an exemplary embodiment of the present invention;

FIG. 3 shows a flowchart illustrating a method of detecting the voltage of an A/D converter according to an exemplary embodiment of the present invention; and

FIG. 4 shows a flowchart illustrating a method of computing and compensating for voltage deviation of a constant voltage device according to an exemplary embodiment of the present invention.

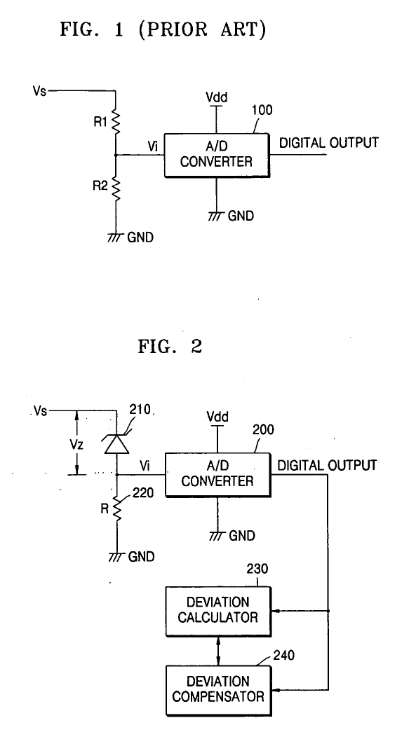

### DETAILED DESCRIPTION OF THE INVENTION

Aspects of the present invention provide a method of measuring variation in voltage applied to an input terminal of an analog-to-digital (A/D) converter. The input voltage is provided via a constant voltage device, which in one exemplary embodiment is a zener diode. Zener diodes are frequently used to generate a constant voltage or a reference supply voltage. Unlike general diodes, voltage is applied to the zener diode in reverse polarity. When a voltage of 30 V or more is applied to a diode in reverse polarity, valence electrons within the diode's semiconductor material break free under the force of the electric field due to the applied voltage. When the field strength is sufficiently large, the free electrons in the semiconductor material accelerate and collide with and knock loose additional electrons, which in turn accelerate and knock loose other electrons. The subsequent collisions due to this effect cause the electrons within the semiconductor material to quickly avalanche. This phenomenon is referred to as the zener effect. During the zener effect, small changes in voltage can cause large changes in current, but the voltage is essentially maintained at a constant value called the zener voltage. In particular, zener diodes are fabricated by adjusting the amount of impurity mixtures within the semiconductor such that the zener effect can occur even when a low voltage is applied to the zener diode. There are two causes that make current suddenly flow through the zener diode when a voltage is applied in reverse polarity,—the above-described avalanche breakdown and a tunneling effect. Tunneling refers to the transport of electrons across a potential barrier without a change in energy. During the zener effect, electrons tunnel from the valance band in the n-type region to the conduction band in the p-type region of the diode, thus causing rapid increase in current.

In general, constant voltage, or a reference supply voltage, is generated in a zener diode during low voltage using the zener breakdown, and generated in a zener diode during high voltage using the in avalanche breakdown. Constant voltage, or the reference supply voltage, can be generated in a zener diode of about 5V using the zener breakdown and the avalanche breakdown at an appropriate ratio of the zener breakdown to the avalanche breakdown.

FIG. 2 is a block diagram of an apparatus for detecting voltage of an A/D converter 200 according to an exemplary embodiment of the present invention. The apparatus includes A/D converter 200, zener diode 210, resistor 220, deviation calculator 230, and deviation compensator 240.

When an analog signal Vi is input to the A/D converter 200, the A/D converter 200 converts the analog signal Vi into a digital signal. Zener diode 210 is a constant voltage device having one end connected to input signal Vs, which is the signal to be detected, and the other end connected to the input terminal of A/D converter 200. Zener diode 210 is maintained at a constant voltage level. The zener diode 210 lowers the voltage of the input signal Vs to an allowed maximum voltage regardless of a variation in the voltage of the input signal Vs.

One end of resistor R 220 is connected to ground GND and the other end is connected to both zener diode 210 and the input terminal of A/D converter 200. Resistor R 220 provides the current path to cause the zener voltage Vz to form across zener diode 210. When the input impedance of A/D converter 200 is equal to or greater than a predetermined value, resistor R 220 may be removed from the exemplary apparatus shown by FIG. 2.

The input voltage to A/D converter 200 is Vi_math when the constant voltage Vz of zener diode 210 has an ideal value with respect to the input signal Vs, and a calibrated measured input voltage of Vi_cal, which represents the actual or measured voltage drop across the zener diode 210. The deviation calculator 230 computes and stores the voltage difference Vcal between the voltages Vi_math and Vi_cal. The deviation calculator 230 may comprise a central processing unit (CPU) and memory.

The deviation compensator 240 compensates for voltage deviation of the zener diode 210 by reflecting the voltage difference Vcal, which is computed by the deviation calculator 230, in the output of the A/D converter 200. In other words, the voltage difference Vcal is reflected in the voltage value of the analog signal Vi input to the input terminal of the A/D converter 200 prior to compensation. The deviation compensator 240 may also comprise a CPU and memory.

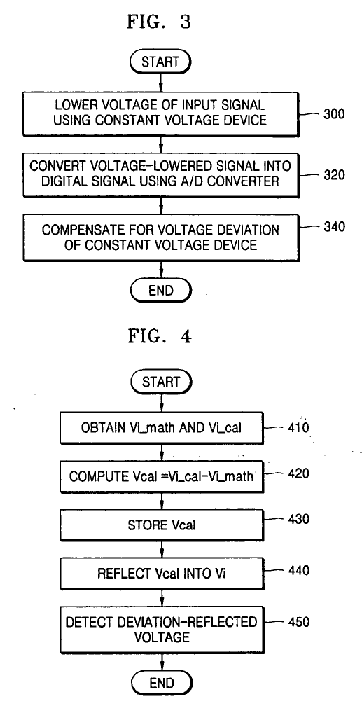

FIG. 3 is a flowchart illustrating a method of detecting the voltage of an A/D converter according to an exemplary embodiment of the present invention. FIG. 4 is a flowchart illustrating a method of computing and compensating for voltage deviation of a constant voltage device according to an exemplary embodiment of the present invention. Operation of an apparatus for detecting the voltage of an A/D converter according to an exemplary embodiment of the present invention will now be described with reference to FIGS. 2 through 4.

When an input signal Vs is input to zener diode 210, the voltage of input signal Vs is lowered by a predetermined voltage Vz by the constant voltage device (step 300). Next, the signal Vi of lowered voltage Vs is converted into a digital signal using A/D converter 200 (step 320). Next, the deviation of the voltage of zener diode 210 with respect to the digital signal is compensated for using the deviation compensator 240 (step 340).

Step 340 will now be described in detail with reference to FIG. 4. First, voltage deviation of the zener diode 210 is computed. It is assumed that the input voltage to the A/D converter 200 is (1) Vi_math, when the constant voltage Vz of zener diode 210 has an ideal value with respect to the input signal Vs, and (2) Vi_cal, when a calibrated input voltage to the A/D converter 200 is obtained, the calibrated voltage representing an actual or measured voltage (step 410). Next, voltage deviation Vcal is obtained by computing a voltage difference between the voltages Vi_math and Vi_cal (step 420). The voltage deviation Vcal is stored in deviation calculator 230 (step 430).

Next, the voltage deviation Vcal of zener diode 210 is compensated for by reflecting the voltage deviation Vcal of zener diode 210, which is computed by the deviation calculator 230, in the output of the A/D converter 200 (step 440). Thereafter, the deviation-compensated voltage is detected (step 450).

In an apparatus and method for detecting the voltage of an A/D converter according to an exemplary embodiment of the present invention, it is possible to precisely detect variation in the voltage of an A/D converter by reducing input voltage, which is initially greater than the supply voltage Vdd applied to the A/D converter, to be lower than the supply voltage Vdd without reducing a variation in the voltage when an analog signal is converted into a digital signal using the A/D converter. Also, it is possible to precisely detect the voltage of the A/D converter by compensating for voltage deviation of a zener diode through calibration.

While the present invention has been particularly shown and described with reference to exemplary embodiments thereof, it will be understood by those skilled in the art that various changes in form and detail may be made therein without departing from the spirit and scope of the present invention as defined by the appended claims.

What is claimed is:

1. An apparatus for detecting a voltage of an analog-to-digital converter, comprising:
a constant voltage device comprising a first end connected to an input signal Vs and a second end connected to an input terminal of the analog-to-digital converter, the constant voltage device being maintained at a substantially constant voltage level Vz plus or minus a voltage deviation.

2. The apparatus as claimed in claim 1,
wherein the voltage deviation represents the difference between an input voltage to the analog-to-digital converter when the constant voltage device has an ideal voltage with respect to the input signal Vs and an actual input voltage to the analog-to-digital converter;
the apparatus further comprising:
a deviation calculator for computing and storing the voltage deviation; and
a deviation compensator for compensating for the voltage deviation of the constant voltage device by reflecting the voltage deviation in an output of the analog-to-digital converter.

3. The apparatus of claim 1, further comprising a resistor comprising a third end connected to a ground voltage and a fourth end connected to both the second end of the constant voltage device and the input terminal of the analog-to-digital converter.

4. The apparatus of claim 1, wherein the constant voltage device comprises a zener diode.

5. The apparatus of claim 2, wherein the constant voltage device comprises a zener diode.

6. The apparatus of claim 2, wherein the deviation calculator comprises a CPU and memory.

7. The apparatus of claim 2, wherein the deviation compensator comprises a CPU and memory.

8. A method of detecting a voltage of an analog-to-digital converter, comprising:
lowering an input signal voltage to a predetermined voltage using a constant voltage device having voltage deviation;
converting the lowered input signal voltage into a digital signal using the analog-to-digital converter; and
compensating for the voltage deviation.

9. The method of claim 8, wherein compensating for the voltage deviation comprises reflecting the voltage deviation in the digital signal.

10. The method of claim 8, wherein the constant voltage device comprises a zener diode.

11. The method of claim 10, further comprising:
determining the voltage deviation of the zener diode by obtaining the difference between an input voltage to the analog-to-digital converter when the zener diode has an ideal voltage with respect to the input signal voltage and an actual input voltage to the analog-to-digital converter.

12. A computer readable medium having stored thereon instructions for detecting a voltage of an analog-to-digital converter, the instructions comprising:
instructions for lowering an input signal voltage to a predetermined voltage using a constant voltage device having voltage deviation;
instructions for converting the lowered input signal voltage into a digital signal using the analog-to-digital converter; and
instructions for compensating for the voltage deviation by reflecting the voltage deviation in the output digital signal
instructions for determining the voltage deviation of the constant voltage device by obtaining the difference between an input voltage to the analog-to-digital converter when the constant voltage device has an ideal voltage with respect to the input signal voltage and an actual input voltage to the analog-to-digital converter.
